(19) United States
(12) Patent Application Publication
(10) Pub. No.: US 2019/0235230 A1
(43) Pub. Date: Aug. 1, 2019

(54) OPTICAL SYSTEM WITH DEFORMABLE MEMS OPTICAL ELEMENT

(71) Applicant: The Governors of the University of Alberta, Edmonton (CA)

(72) Inventors: Roger ZEMP, Edmonton (CA); Zhenhao LI, Edmonton (CA); Afshin Kashani ILKHECHI, Edmonton (CA)

(21) Appl. No.: 16/259,017

(22) Filed: Jan. 28, 2019

Related U.S. Application Data
(60) Provisional application No. 62/622,131, filed on Jan. 26, 2018.

(51) Int. Cl. G02B 26/08; B81B 3/00; B81B 7/02

(52) U.S. Cl. CPC G02B 26/0833; B81B 3/0083; B81B 3/0086; B81B 2203/0315; B81B 2201/042; B81B 2203/0127; B81B 2203/04; B81B 7/02

(57) ABSTRACT

An optical system has a first electrode, and an optical element suspended above the first electrode. The optical element is flexible and comprises a second electrode. An optical element support rigidly supports an outer perimeter of the optical element above the first electrode. A voltage source applies a potential difference between the first electrode and the second electrode, the potential difference causing the optical element to flex and adjust a focal zone of the optical element. An optical source generates a beam. A lens focuses the beam to a lens focal zone in which the beam has a beam width, the beam at the beam width being incident on the optical element.

### TECHNICAL FIELD

This relates to a deformable optical element, and in particular, a deformable MEMS micro-minor or lens that is used to adjust the focus of a beam.

### BACKGROUND

Deformable mirrors are used as adaptive optical elements, such as in mobile applications. The technology to dynamically adjust the focal length of a beam in mobile applications is currently done with slow (˜Hz) motorized translation of a lens including with miniaturized voice-coil actuated focusing and vertical MEMS comb-drive systems. Piezo-mirror actuation can be fast but offers minimal displacements, resulting in minimal (nm-μm scale) change in focal depth, unsuitable for our application. Deformable lenses including liquid lenses offer significant promise for optical focusing, but still have orders of magnitude slower tuning speeds than are needed for future high-speed focusing applications. Deformable-mirror technology has been on the market for some time, but current architectures are designed more for aberration-correction applications with low speed requirements and are not widely used for modifying optical focal depth.

U.S. Pat. No. 4,571,603 (Hornbeck et al) entitled “Deformable mirror electrostatic printer” describes an example of an electrostatically actuated minor.

### SUMMARY

According to an aspect, there is provided an optical system comprising a first electrode and an optical element suspended above the first electrode. The optical element is flexible and comprises a second electrode. An optical element support rigidly supports an outer perimeter of the optical element above the first electrode. A voltage source applies a potential difference between the first electrode and the second electrode, the potential difference causing the optical element to flex and adjust focal zone of the optical element. An optical source generates a beam, and a lens focuses the beam to a lens focal zone in which the beam has a beam width, the beam at the beam width being incident on the optical element.

According to other aspects, the optical system may comprise the following elements, alone or in any reasonable combination: the optical element may be positioned within the lens focal zone; a collimating lens may collimate the beam after the optical element; the optical element may comprise a mirror surface and the potential difference may adjust a focal distance of the mirror surface; the mirror surface may comprise a reflective coating on the optical element; the optical system may further comprise a beamsplitter that decouples incident and reflected light relative to the mirror surface; the beamsplitter may be a polarizing beamsplitter; the optical element may comprise a transparent or semi-transparent layer of material that acts as a lens, and the potential difference may adjust a focal distance of the lens; the potential difference may change a curvature of a lower surface of the optical element that faces the first electrode while a curvature of an upper surface that is opposite the lower surface remains substantially unchanged; the optical system may further comprise a controller that controls the potential difference of the voltage source to achieve a desired curvature of the optical element; in a flexed state, the optical element may comprise a line of inflection within which a curvature of the optical element approximates a parabolic surface; the optical element support may define a cavity between the first electrode and the second electrode; the cavity may comprise a vacuum or may be vented; a top surface of the first electrode may be exposed to a vacuum; the second electrode may be integrally formed with the optical element or may be mounted to the optical element; the optical system may further comprise a dielectric layer on at least one of the first electrode and the second electrode; the mirror surface may comprise a reflective coating on the optical element; the optical beam source may comprise a collimated LED source or a laser; the optical element may have a diameter of less than 500 microns, 200 microns, 100 microns, 50 microns, or 10 microns; and the optical element may have a diameter that is greater than or equal to 5 microns, 10 micros, 20 microns, 100 microns, or 200 microns.

According to other aspects, there is provided an architecture for an ultrafast microscale deformable capacitive MEMS mirror system that modulates the focal wave front curvature of a focused laser beam. The system may comprise a top membrane suspended over a cavity, a top electrode on or doubling as the membrane, a bottom electrode on the other side of the cavity, an optional dielectric layer on the top and/or bottom electrode, an optional reflective coating on the movable membrane (metal, optical thin films), a gap which may be either vacuum sealed or sealed with certain type of gas, or vented, an optional transparent vacuum enclosure fixed above the membrane to minimize the atmospheric pressure on the membrane, a voltage control signal to adjust the bias across the device gap to tune the deflection of the membrane, a controller to drive the membrane with a bias voltage to achieve a desired radius of curvature at the center of the membrane, an incident optical beam, which, for example, may be from a collimated LED source, or a laser beam, a lens or curved minor to focus an optical beam near to the central portion of the membrane and collect reflected light, the optical focal plane may be within a distance from the membrane surface, where the distance is the optical depth of focus, and a beamsplitter or a polarizing beamsplitter to decouple incoming and reflected light.

According to other aspects, an architecture for an ultrafast deformable capacitive MEMS micro-lens system may comprise an optically-transparent top membrane suspended over a cavity, a top transparent electrode on or doubling as the membrane, an optically-transparent bottom electrode on the other side of the cavity, an optional transparent dielectric layer on the top and/or bottom electrode, a top deformable lens material (which may be for example a liquid, gel, or polymer) formed into a planar, concave or convex shape, ideally with the symmetry axis of the lens material aligned with the symmetry axis of the deformable membrane, an optional anti-reflective coatings on the movable membrane, bottom electrode and/or substrate, a voltage-controlled signal to adjust the bias across the device gap to tune the deflection of the membrane, a controller to drive the membrane with a bias voltage to achieve a desired radius of curvature at the center of the membrane, a lens, lens system, or curved minor to focus an optical beam to the central portion of the membrane, an incident optical beam, which, for example, may be from a collimated LED source, or a laser beam, an optional lens or lens system for collecting and collimating or refocusing the light passing through the deformable lens, a gap which is either vacuum sealed or sealed with certain type of gas, or vented, and an optional transparent vacuum enclosure fixed above the membrane to minimize the atmospheric pressure on the membrane.

According to other aspects, a direct wafer-bonding-based fabrication of the ultrafast microscale deformable capacitive MEMS mirrors may comprise one or more of the following step, alone or in combination: using an silicon-on-insulator (SOI) top wafer that contains a handle layer, a box layer and a device layer; using a top wafer that contains a substrate and a membrane layer; using a bottom wafer that contains a substrate, an insulating layer wherein cavities are patterned in the insulating layer; removing the handle and box layers of a top wafer through dry-etch method, or wet-etch method, or a combination of both methods, after bonding the two wafers; removing the substrate of a top wafer through dry-etch method, or wet-etch method, or a combination of both methods, after bonding two wafers; pairing of the wafers to be bonded that may be pairing SOI to oxide, silicon nitride to silicon nitride, silicon nitride to oxide; bonding the top wafer and the bottom wafer with or without alignment during the bonding process; providing a bonding environment may be with or without vacuum; polishing the membrane to minimize the minor's surface roughness in order to satisfy the optical requirements; and providing a reflective layer on top of the membrane to form the mirror surface that may be metals such as Au, Al, Ag, Cr, polished silicon, silicon oxide or other materials that meet the optical requirements.

According to other aspects, a sacrificial-release method of fabricating ultrafast microscale deformable capacitive MEMS minors may comprise one or more of the following steps, alone or in combination: depositing electrodes, sacrificial layers, membrane and minor surface by CVD, PECVD, LPCVD, spin coating, sputtering, electron-beam evaporation, electroplating, thermal oxidation, or other deposition methods; using membrane materials that may be single crystal silicon, poly-silicon, oxide, silicon nitride, organic polymers, metals, or other materials; polishing the membrane to minimize the mirror's surface roughness in order to satisfy the optical requirements; using materials for a reflective layer on top of the membrane to form the minor surface that may be metals such as Au, Al, Ag, Cr, polished silicon, silicon oxide, or other materials that meet the optical requirements; using sacrificial materials that may be single crystal silicon, poly-silicon, oxide, silicon nitride, organic polymers, metals, or other materials; removing the sacrificial layers after depositing the membrane by wet etching methods using KOH, TMAH, BOE, HCL, metal etchants, gas phase etching methods such as vapor HF etching, dry etching methods, or other etching methods; and using a critical dry point method after removing the sacrificial layer to avoid the stiction effect.

According to other aspects, an adhesive wafer-bonding-based fabrication of the ultrafast microscale deformable capacitive MEMS minors or lenses may comprise one or more of the following steps, alone or in combination: providing an SOI top wafer that contains a handle layer, a box layer and a device layer; providing a top wafer that contains a substrate and a membrane layer; providing a bottom wafer that contains a substrate, an insulating layer wherein cavities are patterned in the insulating layer; removing the handle and box layers of a top wafer through dry-etch method, or wet-etch method, or a combination of both methods, after bonding two wafers; removing the substrate of a top wafer through dry-etch method, or wet-etch method, or a combination of both methods, after bonding two wafers; pairing of the wafers to be bonded such that the bonded materials are chosen among silicon, oxide, silicon nitride, glass, ITO, AZO, AIN, metals, organic polymers, and other materials; aligning the top wafer and the bottom wafer during the bonding process; applying adhesive on one or both the top wafer and the bottom wafer; deposition the adhesive layer through spin coating, sputtering methods or other methods; patterning the adhesive layer through a photolithography procedure or a electron beam lithography procedure; patterning the adhesive layer through a lithography procedure with the use of photoresist following with the use of dry etching methods; bonding in an environment that may be with or without vacuum; using a polymer adhesive process at temperatures less than 400° C.; polishing the membrane to minimize the mirror's surface roughness in order to satisfy the optical requirements; and providing a reflective layer on top of the membrane to form the minor surface that may be made from metals such as Au, Al, Ag, Cr, polished silicon, silicon oxide, or other materials that meet the optical requirements.

According to other aspects, an anodic wafer-bonding-based fabrication of the ultrafast microscale deformable capacitive MEMS mirrors or lenses may comprise one or more of the following steps, alone or in combination: providing a SOI top wafer that contains a handle layer, a box layer and a device layer; growing or depositing an insulating layer on the device layer of the top wafer wherein the insulating layer may be oxide or silicon nitride; providing a bottom wafer that is made of glass; patterning cavities in the bottom wafer by either dry etching or wet etching methods; depositing and patterning bottom electrodes within the cavity region by dry etching, or wet etching or lift-off process; removing gas that is generated during the anodic bonding process by using a gas release process and a release hold sealing process; polishing the membrane to minimize the mirror's surface roughness in order to satisfy the optical requirements; and providing a reflective layer on top of the membrane to form the minor surface that may be made of metals such as Au, Al, Ag, Cr, polished silicon, silicon oxide, or other materials that meet the optical requirements.

According to other aspects, a patterning method to determine the shape and the dimension of the cavities may comprise one or more of the following steps, alone or in combination: defining the cavities by pattering the sacrificial layer with lithography process and etching methods; defining the cavities by pattering the photoresist or adhesive layer as a structural layer; defining the cavity by directly etching the device layer such as etching into the silicon membrane with isotropic or anisotropic methods.

In other aspects, the features described above may be combined together in any reasonable combination as will be recognized by those skilled in the art.

### BRIEF DESCRIPTION OF THE DRAWINGS

These and other features will become more apparent from the following description in which reference is made to the appended drawings, the drawings are for the purpose of illustration only and are not intended to be in any way limiting, wherein:

FIG. 1a is a transparent, cut-away, perspective view of a micro-mirror taken along line A-A in FIG. 1b.

FIG. 1b is a transparent, top plan view of a micro-mirror.

FIG. 2a is an elevated side view in section of a micro-mirror in the non-deflective mode taken along line B-B in FIG. 2c.

FIG. 2b is an elevated side view in section of a micro-mirror in the deflective

mode taken along line B-B in FIG. 2c.

FIG. 2c is a transparent, top plan view of a micro-mirror.

FIG. 3a is an elevated side view in cross section of a beam tracing diagram showing the operation of a micro-mirror in the non-deflective mode.

FIG. 3b is an elevated side view in section of a beam tracing diagram showing the operation of a micro mirror in the deflective mode.

FIG. 4a is a transparent, cut-away, perspective view of a micro-lens.

FIG. 4b is a detailed view of a portion of the micro-lens of FIG. 4a.

FIG. 4c is a transparent, top plan view of a micro-lens showing the cut-away lines in FIG. 4a.

FIG. 5a is an elevated side view in section of a micro-lens in the non-deflective mode taken along line E-E shown in FIG. 5c.

FIG. 5b is an elevated side view in section of a micro-lens in the deflective mode taken along line E-E shown in FIG. 5c.

FIG. 5c is a transparent top plan view of a micro-lens.

FIG. 6a is a transparent, cut-away, perspective view of a micro-lens taken along line F-F of FIG. 6c.

FIG. 6b is a detailed view of a portion of the micro-lens in FIG. 6a.

FIG. 6c is a transparent, top plan view of a micro-lens.

FIG. 7a is an elevated side view in section of a micro-lens in the non-deflective mode taken along line H-H shown in FIG. 7c.

FIG. 7b is an elevated side view in cross-section of a micro-lens in the deflective mode taken along line H-H shown in FIG. 7c.

FIG. 7c is a transparent top plan view of a micro-lens. FIG. 8a is a transparent, cut-away, perspective view of a micro-lens taken along line I-I in FIG. 8.

FIG. 8b is a detailed view of a portion of the micro-lens in FIG. 8a.

FIG. 8c is a transparent, top plan view of a micro-lens.

FIG. 9a is an elevated side view in section of a micro-lens in the non-deflective mode taken along line K-K in FIG. 9c.

FIG. 9b is an elevated side view in section of a micro-lens in the deflective mode.

FIG. 9c is a transparent top plan view of a micro-lens showing the cross section line for FIG. 9a and FIG. 9b.

FIG. 10a is an elevated side view in section of a beam tracing diagram showing the operation of a micro-lens in the non-deflective mode.

FIG. 10b is an elevated side view in section of a beam tracing diagram showing the operation of a micro-lens in the deflective mode.

FIG. 11a through 11g depict steps in a fabrication process for a micro-mirror.

FIG. 12a through 12i depict steps in a fabrication process for a micro-lens.

### DETAILED DESCRIPTION OF PREFERRED EMBODIMENTS

The optical system described herein involves the use of a beam of electromagnetic energy, such as a beam of collimated light from LEDs, a beam from a laser source, or other source. The beam follows a beam path, which may be defined by optics as required by a particular application. The beam passes through a lens that is focuses the beam on the deformable optical element, which further focuses the beam as it reflects from or transmits through (or is partially reflected/transmitted) the optical element. As the optical element is deformed, the focal point of the optical element may be adjusted.

As electromagnetic beams are focused by optical elements, they reach their smallest point size within what may be referred to as the focal zone around the focal point of the optical element. The focal zone may be defined, for example, to include the point of highest intensity, and the distance from this point at which the intensity is reduced by a factor of two.

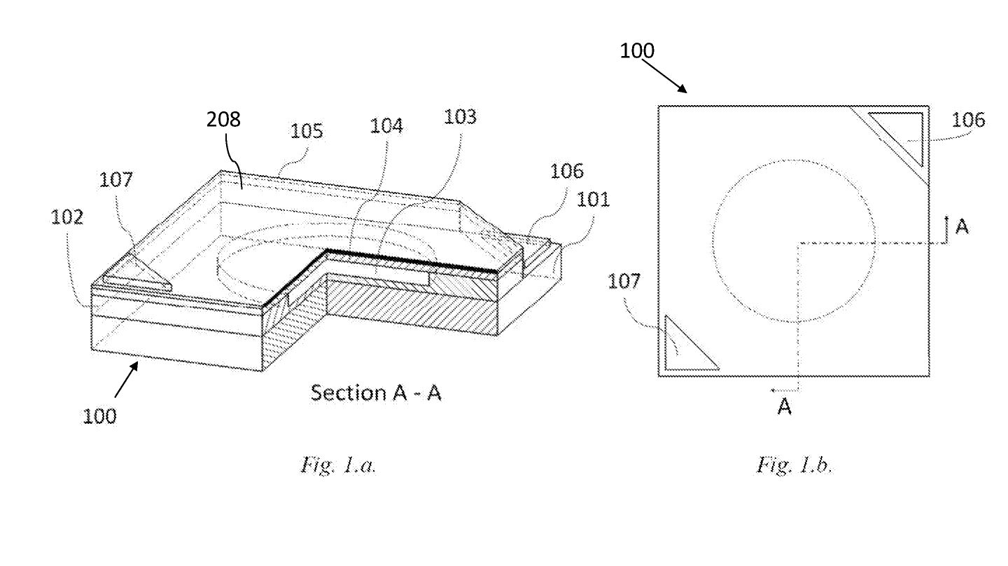

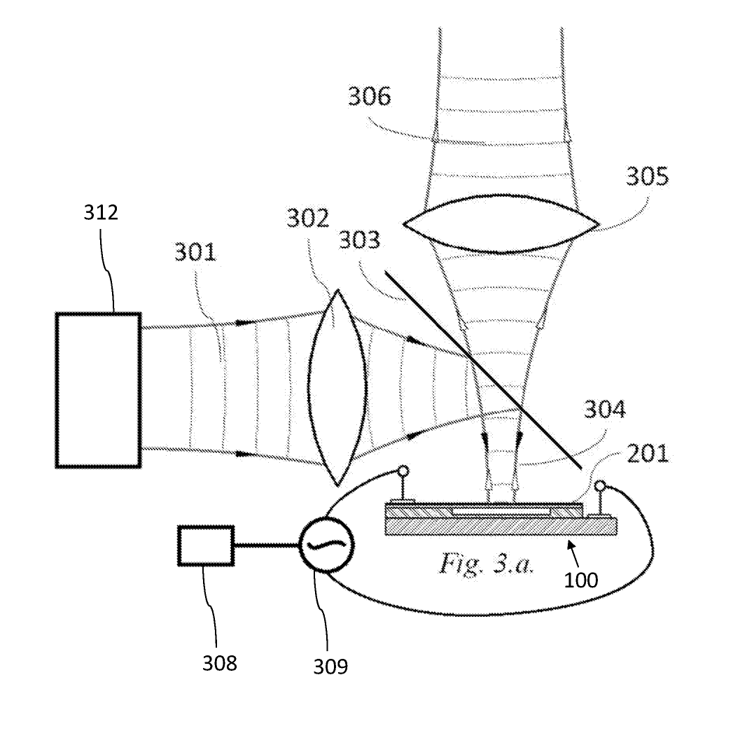

Referring to FIG. 1a, there is shown an optical device 100 that has a first electrode 101, and a second electrode 108 on an optical element 104 that is spaced from first electrode 101. As shown in FIG. 3a, first and second electrodes 101 and 108 are connected to a voltage source 309, which controls the potential difference between the electrodes.

Referring again to FIG. 1a, optical element 104 deforms as a potential difference is applied between the electrodes. As the optical element deforms, the curvature and the focal length of the optical element is changed. As shown, the optical element is a membrane 104 that is supported by an insulating support structure 102, such as a layer with a cavity 103 over which membrane 104 is suspended. As the edges of membrane 104 are fixed, they are unable to move such that the curvature of the membrane has a point, or line, of inflection, at which point the membrane changes from convex to concave. Within this line of inflection, the center of membrane 104, when supported by a round cavity 103, approximates a parabolic shape. This approximation is less accurate as one moves further out from the center of membrane 104 and closer to the line of inflection. As such, it is preferable to focus the beam on the center of the membrane where the membrane is closest to parabolic. In one example, the beam spot is centered on the membrane, and has a diameter that is half or less than half the diameter of the curved portion of the membrane. The optical element can then be used to further focus the beam to a desired size and location. Referring to FIG. 3a, beam 301 originates with a light source 312, and is then directed onto optical element 104. While optical element 104 is depicted as a mirror surface, it will be understood that the necessary components of optical device 100 may be transparent or semi-transparent such that, rather than changing the curvature of a mirror, optical device 100 acts as a variable lens.

It will be understood that, rather than being focused directly on the optical element, a further lens may be included that collimates the beam when the beam is at the smallest beam spot size, or at a sufficiently small beam size based on the dimensions of optical device 100, and prior to the optical element.

By first focusing the beam onto the optical element, the size of the optical element may be reduced, which allows it to be actuated by a smaller voltage signal, and to deform more rapidly than a larger mirror. The size of the optical element will depend on the particular optical system. For example, the optical element may be produced on a micron-scale, such as 5 micron, 10 micron, 20 micron, 50 micron, 100 micron, 200 micron, 500 micron, or therebetween.

An example of a particular optical system is described below with specific details as to how an example may be implemented. Modifications will be apparent to those skilled in the art within the scope of the optical system described herein.

A suitable device may be designed as a Capacitive Micromachined Ultrasound Transducers (CMUTs), which may be reconfigured as fast optical-MEMS deformable mirrors. CMUTs are essentially clamped membrane devices which are electrostatically actuated, and capable of MHz-scale operation in resonant or non-resonant modes. Previous work focused on making these devices efficient ultrasound transducers, such as for use in transformative biomedical imaging applications. CMUTs may be used in a different way. By electrostatically changing the radius of curvature of the membrane, in this case with the membrane doubling as a deformable mirror, the effective radius of curvature of an incident beam wavefront can be changed to move the effective optical focus, as shown in FIGS. 3a & 3b, over a wide range of distances, even though the membrane need only move a small amount, such as less than 100 nm in some examples. Because the mass to move is tiny, and the distances to move are small, the minor-membrane can be moved at extremely high speeds, unlike voice-coil or MEMS comb-drive lens focusing technology prevalent in smart-phones.

Capacitive Micromachined Ultrasound Transducer (CMUTs):

CMUTs may be fabricated using surface micromachining with a sacrificial release process and wafer bonding, or by other methods known in the art. In the embodiment presented below, wafer-bonded CMUTs are used as top membranes that may be formed using the device layer of an Silicon on Insulator (SOI) wafer, which may be manufactured with near atomically-smooth surface roughness, ideal for optical systems.

Adapting CMUTs to Fast Deformable Mirrors and Feasibility Calculations:

CMUTs may be used as fast-deformable mirrors for tunable depth focusing. The basic idea behind the proposed fast-optical focusing technology is shown in FIGS. 3a & 3b. A lens focuses a collimated beam 301 to a point on the CMUT membrane, routed through a beam-splitter 303. As the CMUT deflects, it modifies the radius of curvature of the beam to affect the divergence and focal point of the reflected light. The deflection profile is close to parabolic within the center of the membrane. The deformation profile of circular-membrane CMUT of radius a may be defined as h(r)=(1−(r/a)²)², where r is the radial distance from the center. The radius of curvature at the center is calculated as ROC=a²/4h₀, where h₀=h(0) is the height of deflection at the center of the membrane. A CMUT can change its radius of curvature from infinite (flat) to that of ˜mm with only ˜100 nm membrane deflection. This is enough to change the effective curvature of a Gaussian beam and move its effective focal waist ˜mm distances.

According to one model, the curvature of a Gaussian beam (z)=z(1+(z_{R}/z)²) as a function of distance z is affected by a concave mirror with a given radius of curvature (ROC) and focal length. It is assumed the incident Gaussian beam has focal waist w₀ and wavelength λ where z_{R}=πw₀²/λ is the Rayleigh range. The effective focal length of the concave mirror is f_{M}=ROC/2. Then apply the equation for focusing of a Gaussian beam:

$$\frac{1}{{f}_{M}} = \frac{1}{{s}_{i}} + \frac{1}{{s}_{0} + {z}_{R}^{2} / ( {s}_{0} - {f}_{M} )}$$

where s₀ and sᵢ are the object and image distances respectively. In this case the object distance refers to the point at which the incident beam is focused. With a Gaussian beam having a 20 μm focal waist, and given a 50 μm-radius CMUT membrane deflecting from 0 to 100 nm (300 nm gap), the effective image focal distance sᵢ can be shifted by 1.2 mm. This can be even greater distances by using a lens system. For example: a lens with focal length f=3 mm is used and the object (beam at waist) is s₁=4 mm from the thin lens. Then given the lens equation 1/f=1/s₁+1/s₂, the beam will be refocused at s₂=12 mm at the other side of the lens. If the curvature of the beam is adjusted using the CMUT such that the effective s₁ moves 0.5 mm then s₂ moves to 21 mm away. This is enough to make a significant difference for perceived distances, especially at close range.

Key differences in the MEMS deformable mirror technology discussed herein compared to existing approaches are: (1) the size of the membrane is preferably minimized as much as possible. Preferably, the diameter of the membrane is on the order of microns, such as more or less than 5, 10, 20, 50, 100, 200, and 500 microns, rather than the more common diameter that is on the order of centimeters. This reduces the mass to be moved and leads to higher speeds of operation; (2) the curvature of the membrane is preferably adjusted close to the focal waist where the beam is as small as possible—in this regime ray optics calculations are not applicable and full diffractive effects must be accounted for with Gaussian beam calculations used as a starting point; (3) the membrane dynamics may occur at high speeds (MHz-range), which may require dynamic models of operation and control not accounted for by quasi-static operation modes of other MEMS deformable mirror technology. This is a regime where ultrasonic effects and nonlinear electro-mechanical effects must be accounted for.

CMUTS that have been adapted to provide tunable focusing of electromagnetic energy are referred to as Capacitive Micromachined Optical Focusing (CMOF) MEMS. CMOFs may have a miniature circular mirrored-membrane which can be electrostatically actuated to change minor curvature. The change of the radius of curvature of the CMOF is related to the size of the membrane and the spacing between the top and bottom electrodes. The central deflection zone is a close approximation to a parabolic mirror. The device is fabricated to be only slightly larger than a diffraction-limited focus of a Gaussian beam so there is minimal membrane mass. CMOFs are a good candidate for fast tuning of the radius of curvature of laser beams at greater than MHz tuning rates, a feat difficult to achieve with other current technologies. High-speed focusing CMOF MEMS platform may be described via an equivalent circuit model. The model is capable of full nonlinear analysis of the CMOFs, and it is validated by ANSYS finite element method (FEM) simulations. By using the equivalent circuit model, the non-linear transient response of a CMOF can be rapidly obtained and controlled with nonlinear control systems.

An embodiment of a micro-minor optical device 100 is illustrated in FIGS. 1a and 1b. As shown in FIG. 1a, micro-minor 100 consists of a substrate that is used as first electrode 101, an insulating support layer 102 on top of the substrate with a cavity 103 patterned therewithin, a membrane layer 104 on top of insulating support layer 102, and a reflective layer 105 on top of membrane layer 104. At least one of membrane layer 104 and reflective layer 105 are electrically conductive. Thus, membrane 104 and reflective layer 105 form second electrode 108. First electrode 101 is exposed and then the bottom and top bonding pads 106 and 107 are deposited and patterned to provide access to an electrical connection to first and second electrodes 101 and 108, respectively. Cavity 103 may be a vacuum or vented to the outside of micromirror 100. The top the second electrode 108 or the top of membrane 104 also may be exposed to a vacuum.

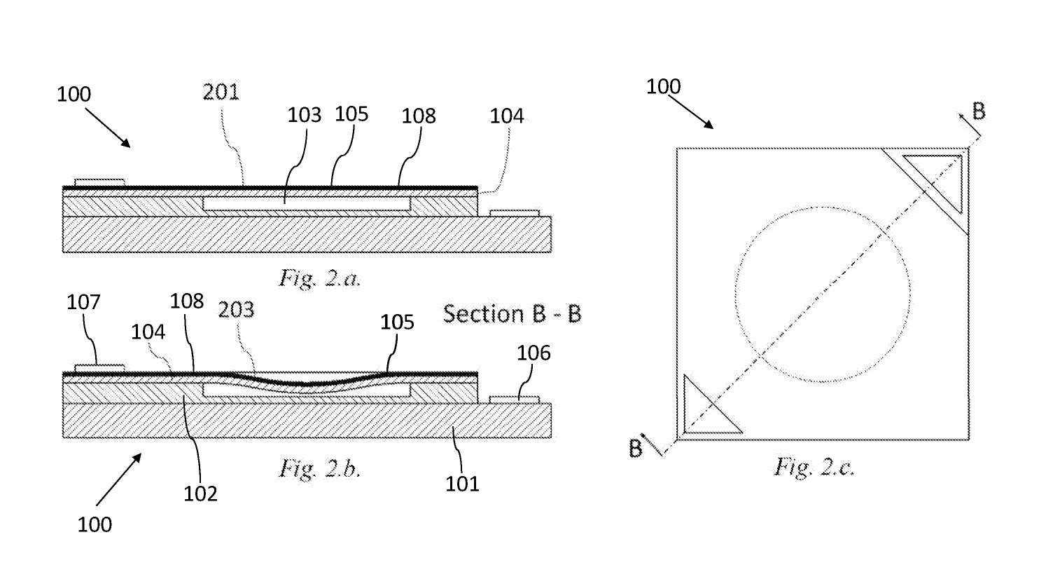

The two operation modes of the preferred embodiment of the micro-minor optical device 100 in FIGS. 1a and 1b are depicted in FIG. 2a. FIG. 2a shows when micro-minor 100 is in the non-deflected mode 201, in which membrane layer 104 and reflective layer 105 are flat. FIG. 2b shows micro-minor 100 in deflective mode 203, in which membrane 104 and a reflective layer 105 are flexed toward first electrode 101 and have a curvature in response to a potential difference applied between first electrode 101 and second electrode 108. The deflection of reflective layer 105 follows the deflection shape of the membrane 104.

FIGS. 3a and 3b depict the operation for micro-mirror 100 to change the focal point of a focused laser beam. FIG. 3a shows an optical source 300 that provides an incident laser beam 301 that is focused on the reflective layer 105 in the non-deflected mode through a lens system 302 and a beam splitter 303. Optical source may alternatively provide a collimated LED beam. Lens 302 may be an aberration-free lens or other types of lens known in the art. The reflected laser beam 304 from the micro-minor 100 transmits through the beam splitter 303 and another focusing lens system 305. Beam splitter 303 may be a polarizing beam splitter. The lens system 305 may also be aberration-free lenses. It will be understood that lens systems 302 and 305 may be a single lens or a combination of lenses and other optical equipment capable of focusing the laser beam. The focal point of the lens system 305 is aligned on the surface of the reflective layer 105 resulting in a collimated laser beam 306 at the output when micro-minor in non-deflective mode 201. FIG. 3b depicts the laser behavior when micro minor 100 is in deflective mode 203. A controller 308 provides instructions to a voltage source 309 to apply a voltage between first and second electrodes 101 and 108 to cause membrane 104 to flex and micro-minor to enter the deflective mode. The incident laser beam 301 is focused on the deflected reflective layer 105 through a lens 302 and a beam splitter 303. The lens system 302 may be aberration-free lenses. The focused laser beam has a flat wavefront at a beam waist 312, which may be aligned at the deflective reflective layer 105 allowing the wavefront of the beam to follow the curvature of the deflected surface of the reflective layer 105. As a result, the reflected laser beam from a deflected reflective surface 105 will have a different wavefront compare to the one from reflective surface 105 in the non-deflective mode resulting the change of a focal zone 311 of an output laser beam 307.

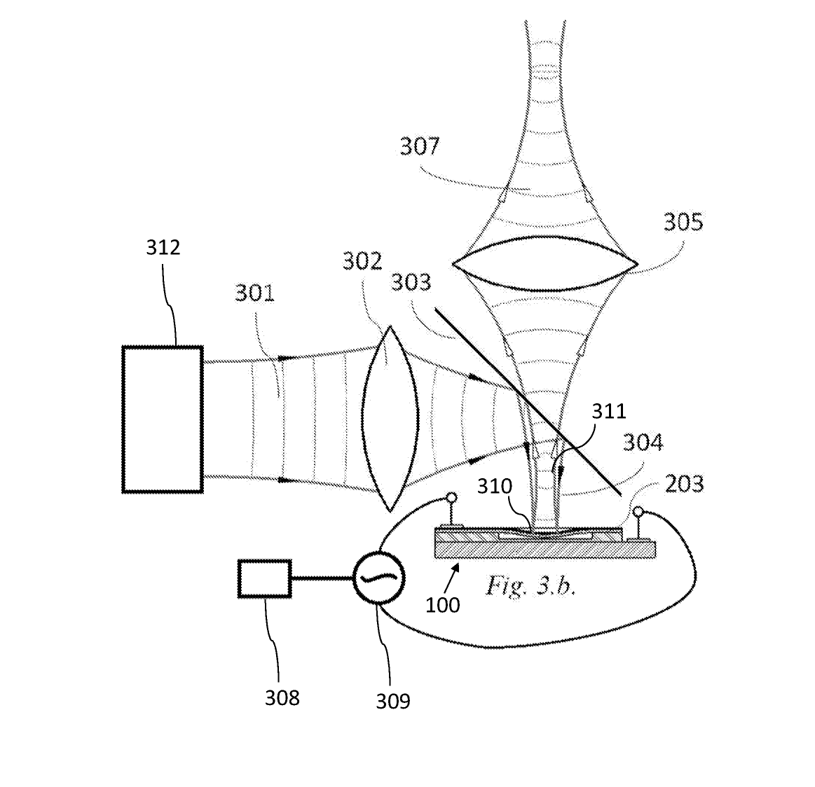

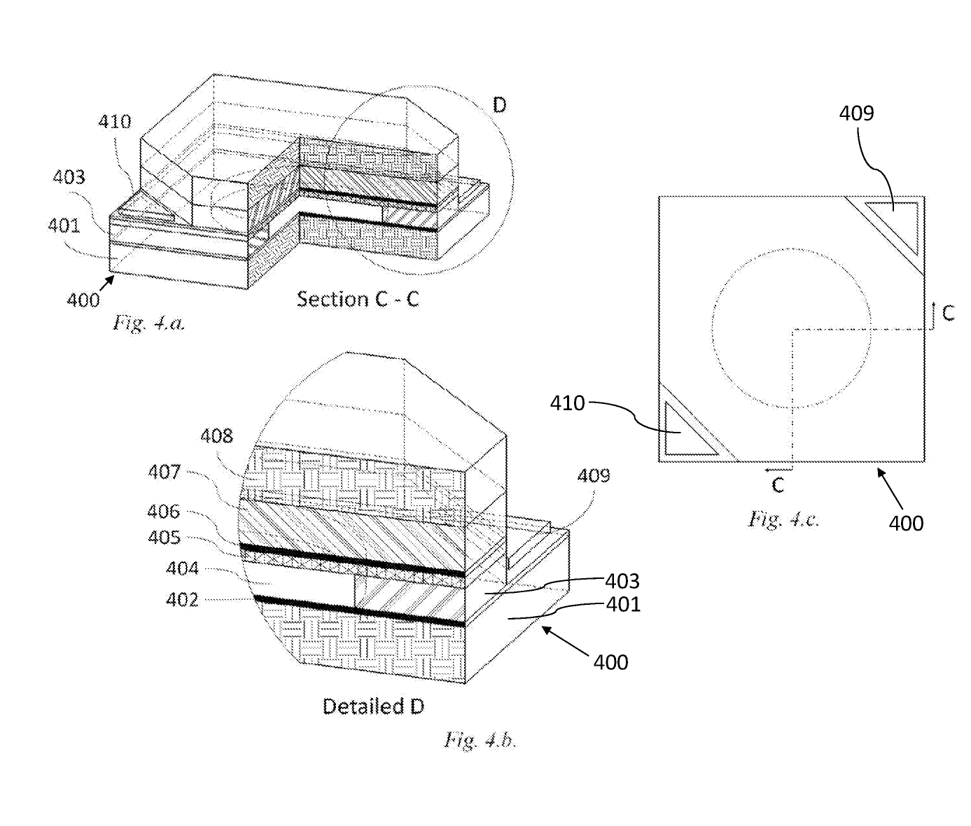

One embodiment of a micro-lens optical element 400 is illustrated in FIG. 4a-4c and FIG. 5a-5c. As shown in FIG. 4a micro-lens 400 consists of a substrate 401, a conductive layer on top of substrate 401 as a first electrode 402, an insulating support layer 403 on top of first electrode 402 with cavities 404 patterned therewithin, a membrane layer 405 on top of insulating support layer 403, a top conductive layer as a second electrode 406 on top of membrane layer 405, an elastic dielectric layer 407 on second electrode 406, and a protective rigid layer 408 on top of elastic dielectric layer 407. All of these components are transparent or semi-transparent to the wavelength of the interested incidence light. The protective rigid layer 408 and the elastic dielectric layer 407 are etched to expose the top electrode, which is made of the second electrode 406. Protective rigid layer 408, elastic dielectric layer 407, second electrode 406, the membrane 405, and the insulating support layer 403 are etched through to expose the bottom electrode, which is made of the first electrode 402. Then, metallic bonding pads 409 and 410 are deposited and patterned on the two conductive layers in order to provide electrical access the first and second electrodes 402 and 406, respectively.

The two operation modes of the micro-lens 400 in FIG. 4 are illustrated in FIG. 5. FIG. 5a shows when the micro-lens is in non-deflective mode 501, which shows a flat membrane 405, a flat second electrode 406, and an elastic dielectric layer 407 with both a top surface 504 and a bottom surface 505 that are flat. FIG. 5b shows when the micro-lens is in deflective mode 503, which shows a deflected membrane 405, and a deflected second electrode 406. Bottom surface 505 of the elastic dielectric layer 407 is deflected while top surface 504 of the elastic dielectric layer 407 remains flat. The deflection of the second electrode 406 and the deflected bottom surface 505 of the elastic dielectric layer 407 follow the deflection shape of the membrane 405. When membrane 405 and second electrode 406 are deflected the top of elastic dielectric layer 407 or rigid layer 408 may remain flat.

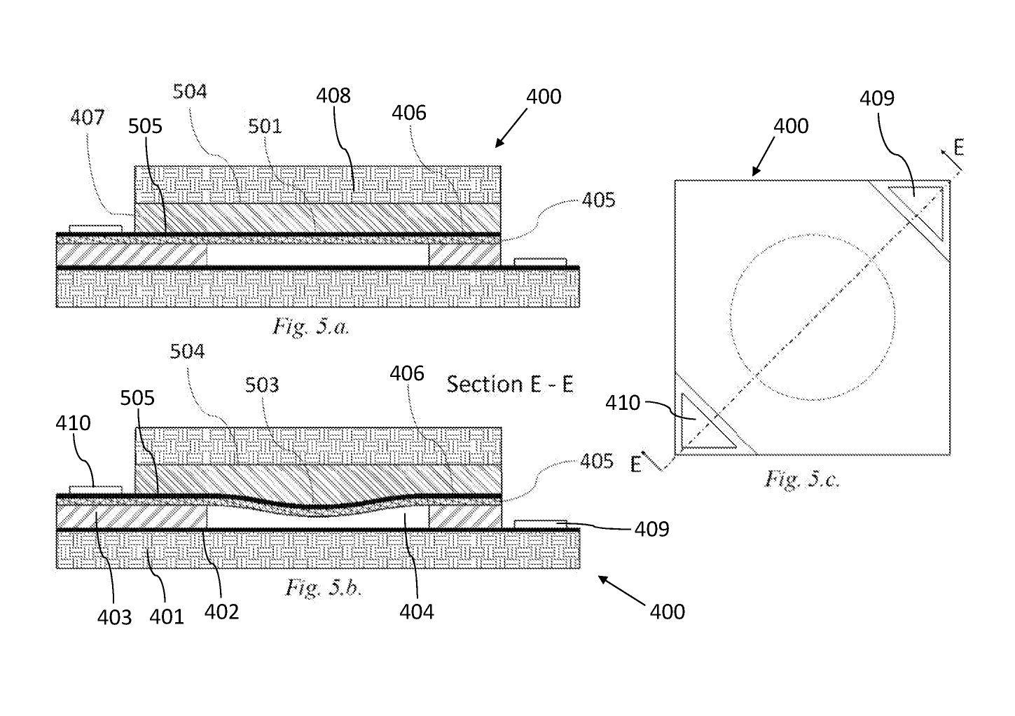

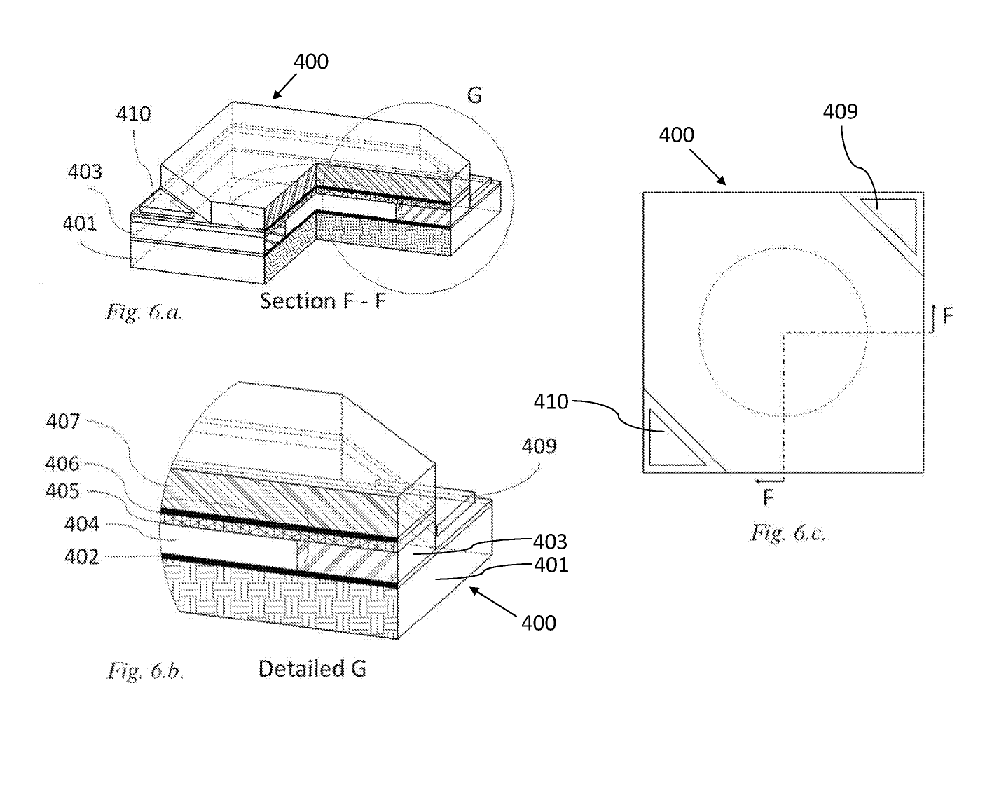

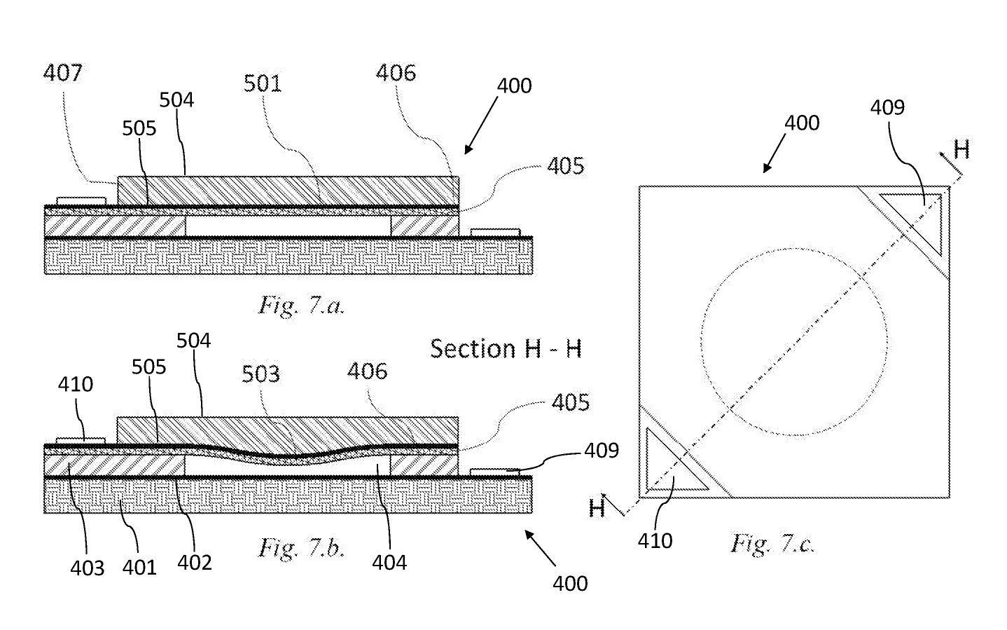

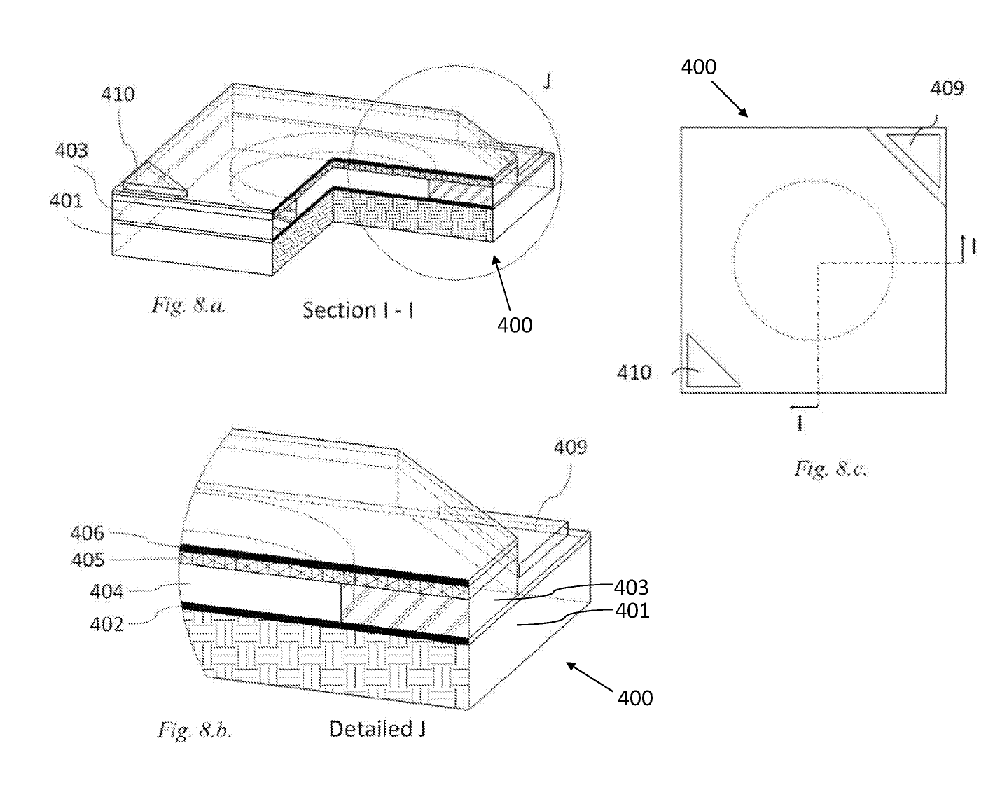

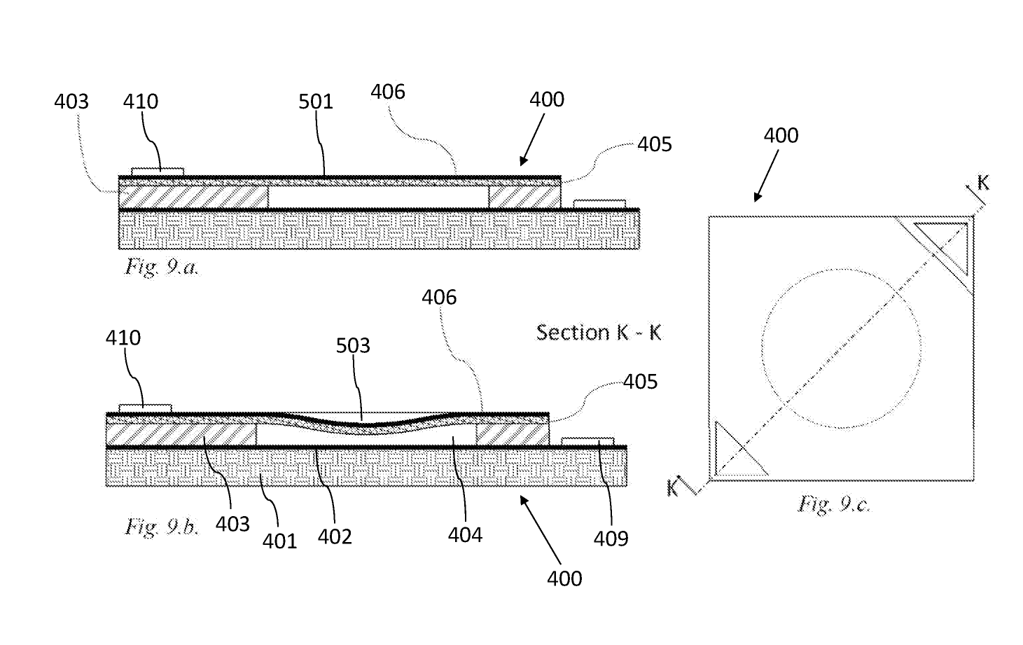

In another embodiment depicted in FIGS. 4a to 5c, a protective rigid layer 408 may be removed from the structure of a micro-lens 400. to achieve a structure as shown in FIG. 6a-6c. The two operational modes of the micro-lens 400 depicted in FIG. 6 are illustrated in FIG. 7a-7c. FIG. 7a shows when micro-lens 400 is in non-deflective mode 501 and FIG. 7b shows micro-lens 400 in deflective mode 503. Both the protective rigid layer 408 and the elastic dielectric layer 407 may also be removed, as shown in FIG. 8a-8c. The two operational modes of the micro-lens 400 depicted in FIG. 8 are illustrated in FIG. 9a-9c. FIG. 9a shows when the micro-lens 400 is in a non-deflective mode 501 and FIG. 9b shows when the micro lens 400 is in a deflective mode 503.

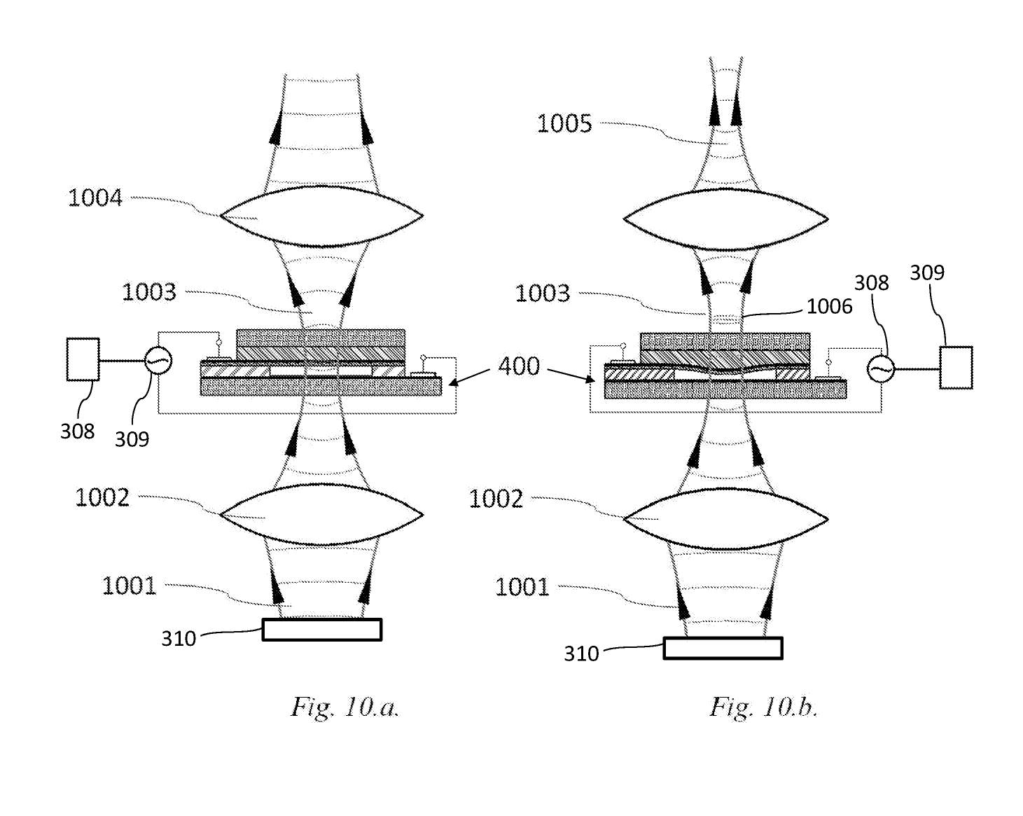

FIGS. 10a and 10b depict the operation of applying micro-minor 400 to change a focal zone 1006 of a focused laser beam. As illustrated in FIG. 10a, the incident laser beam 1001 from an optical source 300 is focused with a lens system 1002 on micro-lens 400. Beam 1001 may be a laser or a collimated LED beam. The lens system 1002 may be aberration-free lenses. The laser beam 1003 that transmitted through the micro-lens 400 is recollimated with a lens system 1004. The lens system 1004 may be aberration-free lenses. When the micro-lens is operated in the deflected mode after controller 309 has instructed voltage source 308 to apply a potential difference between first and second electrodes 402 and 406, as shown in FIG. 10b, micro-lens 400 refocuses the focused beam from the lens system 1002. Therefore, the focal zone 1006 of the output focused beam 1005 can be adjusted by controlling the deflection of membrane 405 and the second electrode 406.

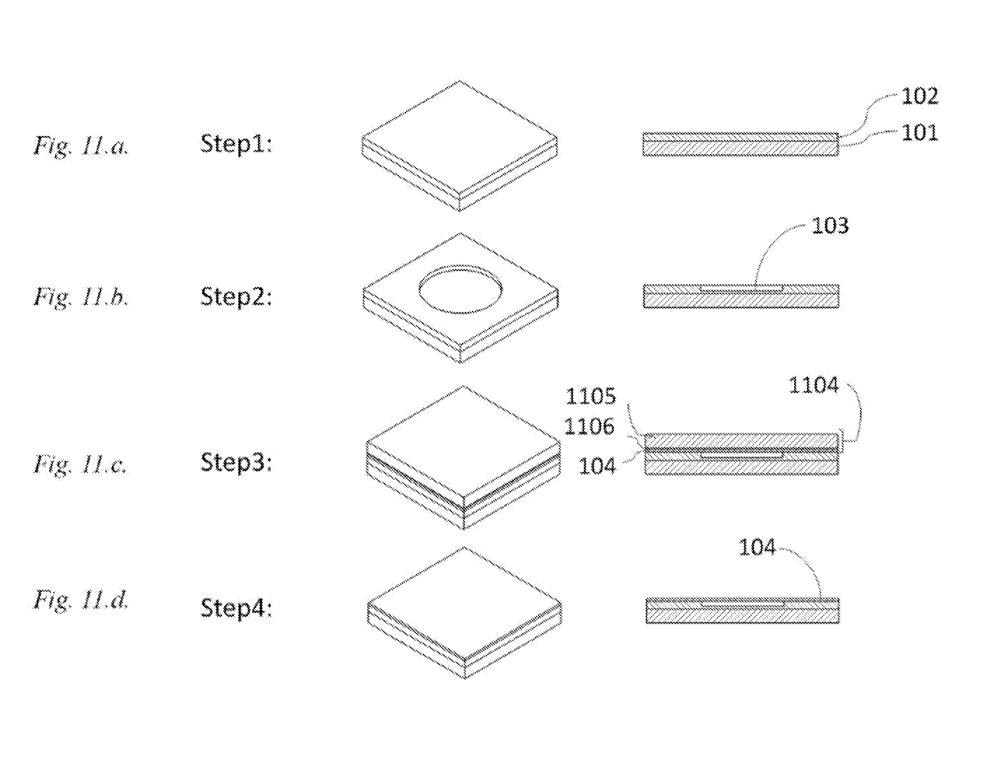

FIG. 11a-11g describes a fabrication process to create micro-minor 100. The process is designed based on a fusion wafer bonding technique. It will be understood that there may be other fabrication methods known in the art that can produce micro-minor 100. A layer of thermal oxide, i.e. insulating support layer 102, is grown on silicon substrate first electrode 101 in the first step to form the bottom wafer. Cavities 103 are then patterned in the insulating support layer 102. An SOI wafer 1104, which is used as a top wafer, is bonded to the bottom wafer by fusion bonding technique in the step 3. The handle layer 1105 and the box layer 1106 are removed in the next step (step 4) to release the membrane 104 (device layer of the SOI wafer). In step 5, a layer of Chromium/gold (Cr/Au) is deposited on the membrane 104 to form reflective layer 105 and second electrode 108. Then in step 6, the silicon substrate 101, which is used as the bottom electrode, is exposed by etching through the Cr/Au layer 105, the membrane 104 and the oxide layer 102. In the last step, bonding pads 106 and 107 are deposited and patterned on the silicon substrate 101 and the Cr/Au layer 105, respectively, in order to access the bottom and the top electrodes.

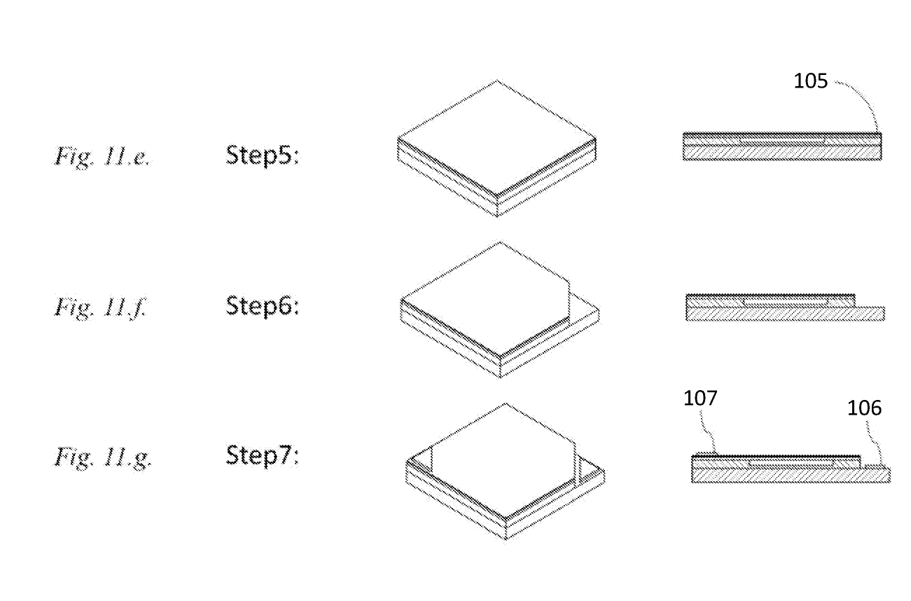

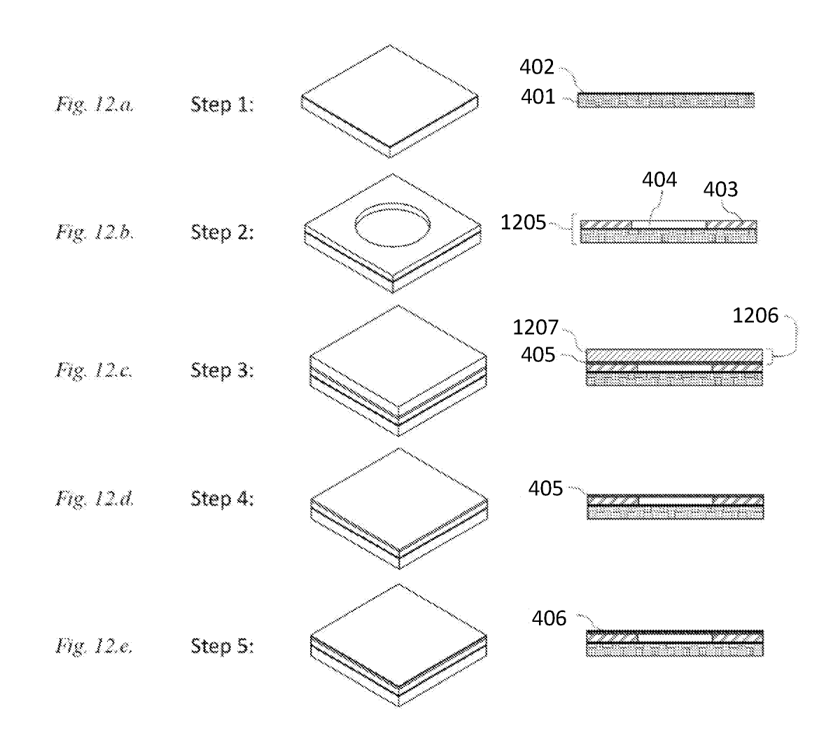

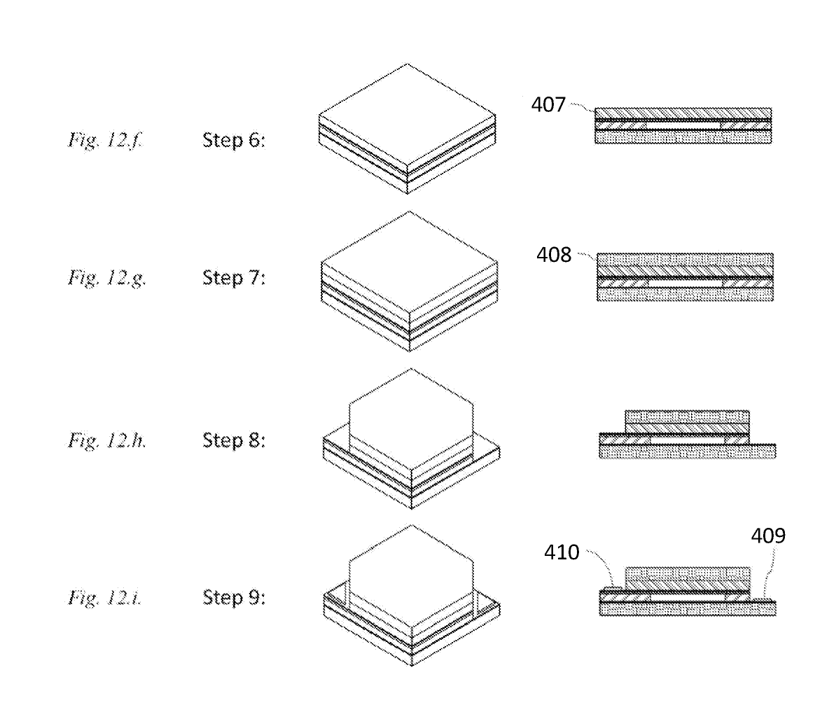

FIG. 12a-12i depicts an example of a fabrication process for micro-lens 400. It will be understood that other fabrication processes known in the art may be used to fabricate micro-lens 400. The process is designed based on the adhesive wafer bonding using photosensitive benzocyclobutene (photo BCB). The adhesive may be other adhesive materials such as SU-8 photoresist or other adhesive materials known in the art. In the first step shown in FIG. 12a, a layer of transparent conductive material is deposited on a transparent substrate 401 to create first electrode 402. The transparent conductive material may be indium tin oxide (ITO) or other transparent conductive material. In FIG. 12b, insulating support layer 403 is formed by spin coating photo BCB on the surface of first electrode 402 with cavities 404 patterned therewithin by lithography process. At this stage, a bottom wafer 1205 that contains a glass substrate 401, an transparent first electrode 402, and an insulating support layer 403 is ready to use. A top wafer 1206 made of a silicon wafer 1207 with a layer of silicon nitride deposited through low stress chemical vapor deposition (LPCVD) process. The silicon nitride layer will form membrane layer 405. In FIG. 12c, membrane layer 405 on the top wafer 1206 is bonded to the photo BCB insulating layer 403 by applying heat and compressive force in a vacuum environment. Silicon nitride membrane layer 405 is released in FIG. 12d by removing the silicon substrate 1207 using KOH wet etching. In the FIG. 12e, another layer of ITO is deposited on the silicon nitride membrane layer 405 to form second electrode 406. In FIG. 12f, a layer of transparent and elastic dielectric layer 407 is coated and cured on the second electrode 406. Dielectric layer 407 may be polydimethylsiloxane (PDMS) or other transparent elastic dielectric materials may be used. In FIG. 12g, rigid transparent layer 408 is bonded to the elastic dielectric layer 407. If glass is used as the rigid transparent layer 408 and the PDMS is used as the elastic dielectric layer 407, one can coat the uncured PDMS on the top conductive layer 406 and directly attach the glass with the uncured PDMS. After curing the PDMS, both the PDMS and the glass are well adhered with the second electrode 406. In FIG. 12h, the rigid layer 408, the elastic dielectric layer 407, the top conductive layer 406, the silicon nitride membrane 405 and the photo BCB insulating layer 403 are etched through to expose the first electrode 402. Also, the rigid layer 408 and the elastic dielectric layer 407 are etched through to expose the second electrode 406. Then, in FIG. 12i, metal pads 409 and 410 are deposited and patterned on the first electrode 402 and second electrode 406 in order to access the electrodes.

In this patent document, the word “comprising” is used in its non-limiting sense to mean that items following the word are included, but items not specifically mentioned are not excluded. A reference to an element by the indefinite article “a” does not exclude the possibility that more than one of the elements is present, unless the context clearly requires that there be one and only one of the elements.

The scope of the following claims should not be limited by the preferred embodiments set forth in the examples above and in the drawings, but should be given the broadest interpretation consistent with the description as a whole.

What is claimed is:

1. An optical system, comprising:
a first electrode;
an optical element suspended above the first electrode, the optical element being flexible and comprising a second electrode;
an optical element support that rigidly supports an outer perimeter of the optical element above the first electrode;
a voltage source that applies a potential difference between the first electrode and the second electrode, the potential difference causing the optical element to flex and adjust a focal zone of the optical element;
an optical source that generates a beam; and
a lens that focuses the beam to a lens focal zone in which the beam has a beam width, the beam at the beam width being incident on the optical element.

2. The optical system of claim 1, wherein the optical element is positioned within the lens focal zone, or wherein a collimating lens collimates the beam after the optical element.

3. The optical system of claim 1, wherein the optical element comprises a mirror surface and the potential difference adjusts a focal distance of the mirror surface.

4. The optical system of claim 3, wherein the mirror surface comprises a reflective coating on the optical element.

5. The optical system of claim 3, further comprising a beamsplitter that decouples incident and reflected light relative to the mirror surface.

6. The optical system of claim 5, wherein the beamsplitter is a polarizing beamsplitter.

7. The optical system of claim 1, wherein the optical element comprises a transparent or semi-transparent layer of material that acts as a lens, and the potential difference adjusts a focal distance of the lens.

8. The optical system of claim 7, wherein the potential difference changes a curvature of a lower surface of the optical element that faces the first electrode while a curvature of an upper surface that is opposite the lower surface remains substantially unchanged.

9. The optical system of claim 1, further comprising a controller that controls the potential difference of the voltage source to achieve a desired curvature of the optical element.

10. The optical system of claim 1, wherein, in a flexed state, the optical element comprises a line of inflection within which a curvature of the optical element approximates a parabolic surface.

11. The optical system of claim 1, wherein the optical element support defines a cavity between the first electrode and the second electrode.

12. The optical system of claim 11, wherein the cavity comprises a vacuum or is vented.

13. The optical system of claim 1, wherein a top surface of the first electrode is exposed to a vacuum.

14. The optical system of claim 1, wherein the second electrode is integrally formed with the optical element, or mounted to the optical element.

15. The optical system of claim 1, further comprising a dielectric layer on at least one of the first electrode and the second electrode.

16. The optical system of claim 1, wherein the optical beam source comprises a collimated LED source, or a laser.

17. The optical system of claim 1 wherein the optical element has a diameter of less than 500 microns, 200 microns, 100 microns, 50 microns, or 10 microns.

18. The optical system of claim 1, wherein the optical element has a diameter that is greater than or equal to 5 microns, 10 micros, 20 microns, 100 microns, or 200 microns.

19. The optical system of claim 1, wherein the optical element comprises a flexible membrane supported by the optical element support.
